(19) United States
(12) Patent Application Publication
(10) Pub. No.: US 2011/0149508 A1
(43) Pub. Date: Jun. 23, 2011

(54) Anti-Vibration Rack with Anti-Vibration Server Slide Rail Module

(76) Inventor: Mohammad Ghassem Malekmadani, Palo Alto, CA (US)

(21) Appl. No.: 12/911,724

(22) Filed: Oct. 25, 2010

Related U.S. Application Data
(63) Continuation-in-part of application No. 12/476,239, filed on Jun. 1, 2009.
(60) Provisional application No. 61/254,716, filed on Oct. 25, 2009.

(51) Int. Cl. H05K 7/20; H05K 7/18; F16F 7/00

(52) U.S. Cl. 361/679.48; 211/26

(57) ABSTRACT

A novel apparatus and system for dampening vibrational forces from servers and electronic components is provided. According to one embodiment, the present invention generally provides a rack for dampening vibration including: at least two elongated structural members, at least two elongated base members, at least one opening along the length of each of the at least two elongated members, at least two cross bar supports, wherein each one of the at least two cross bar supports is coupled to at least one of the at least two elongated structural members; and at least two anti-vibration modules coupled to each of the at least two cross bar supports, wherein the at least two anti-vibration modules are loaded by exerting a force on the anti-vibration modules. In one embodiment, the cross bar housings contacts the cross bar support to provide additional support.

### CROSS-REFERENCE TO RELATED APPLICATIONS

This application is a continuation-in-part pursuant to 37 C.F.R. §1.53(b) of U.S. patent application Ser. No. 12/476,239 filed Jun. 1, 2009, and U.S. Provisional Patent Application Ser. No. 61/254,716 filed Oct. 25, 2009, both of which are incorporated herein by reference in their entirety for all purposes.

### FIELD OF THE INVENTION

The invention relates generally to shelf and rack systems for servers and electronic components and more particularly to apparatus and methods for minimize vibration from servers and electronic components.

### BACKGROUND

Data centers and server racks are extremely noisy places. The noise resulting from vibration can be significant. Multiple sources of vibration contribute to the vibration level of server racks in data centers including but not limited to Computer Room Air Conditioners (CRACS) for building and racks, chillers, building, rack, and server transformers, building/rack Un-interruptible Power Supplies (UPS) and rack/server/Hard Disc Drives (HDD) and cooling fans. These are all very noisy and collectively create a very complex and high level of vibration at wide ranges of frequency. Vibration levels at data centers, server racks and servers vary and typically can be 1 g or more.

Existing server racks are fabricated without vibration dissipating measures. Generally made from steel sheet metal, existing rack structures actually magnify vibration rather mitigating it.

Hard Disc Drives are very sensitive to vibration. When looking for a file to read, the head is moving inward or outward as the disc is spinning, in order to locate the beginning of the file. Vibration makes this task more difficult as the head searches for the file location on the disc. HDD manufacturers have implemented vibration sensors in the HDDs to sense vibration and pause I/O operation in presence of high vibration. Input/Output (I/O) becomes much faster and more efficient as vibration is suppressed. Generally, write operations take longer than read operations and are more sensitive to vibration. Many server/computer operations are I/O—intensive workloads, e.g. On-line transaction processing (OLTP) applications, video streaming, web serving, finance applications, etc.

Vibration at wide ranges of frequencies interferes with HDD operation and in some cases causes the corresponding server or computer to shut down. As a result, there is a need for anti-vibration measures at various frequencies to dissipate vibration in servers allowing HDDs to perform much more efficiently.

The relationship between an arbitrary vibration force F and the resulting motion X of a multiple degree of freedom structure can be presented as: MX″+CX′+KX=F

Where X is displacement (motion), X′ velocity, X″ is acceleration, M represents mass, C damping and K stiffness of the structure. Stiffness and damping properties of materials and structures vary with operational frequencies.

Embodiments of the novel anti vibration rack optimize structural stiffness and damping to mitigate vibration at all operating frequencies in servers and data centers.

The selection of materials may also influence the performance of a system. Materials that aid in minimizing vibration exist. An example of such is carbon fiber composites.

Carbon fiber generally refers to carbon filament thread, or to felt or woven cloth made from those carbon filaments. The term carbon fiber is also used to mean any composite material made with carbon filament, such a material is sometimes referred to as graphite-reinforced plastic.

Each carbon filament is made out of long, thin filaments of carbon sometimes transferred to graphite. A common method of making carbon filaments is the oxidation and thermal pyrolysis of polyacrylonitrile (PAN), a polymer used in the creation of many synthetic materials. Like all polymers, polyacrylonitrile molecules are long chains, which are aligned in the process of drawing continuous filaments. When heated in the correct conditions, these chains bond side-to-side (ladder polymers), forming narrow graphene sheets which eventually merge to form a single, jelly roll-shaped or round filament. The result is usually 93-95% carbon. Lower-quality fiber can be manufactured using pitch or rayon as the precursor instead of PAN. The carbon can become further enhanced, as high modulus or high strength carbon, by heat treatment processes. Carbon heated in the range of 1500-2000° C. (carbonization) exhibits the highest tensile strength (820,000 psi or 5,650 MPa or 5,650 N/mm²), while carbon fiber heated from 2500 to 3000° C. (graphitizing) exhibits a higher modulus of elasticity (77,000,000 psi or 531 GPa or 531 kN/mm²).

There are several categories of carbon fibers: standard modulus (250 GPa), intermediate modulus (300 GPa), and high modulus (>300 GPa). The tensile strength of different yarn types varies between 2000 and 7000 MPa. The density of carbon fiber is 1750 kg/m3.

Precursors for carbon fibers are PAN, rayon and pitch. In the past rayon was more used as a precursor and still is for certain specialized applications such as rockets and specific aerospace applications. Carbon fiber filament yarns are used in several processing techniques: the direct uses are for prepregging, filament winding, pultrusion, weaving, braiding and the like.

The filaments are stranded into a yarn. Carbon fiber yarn is rated by the linear density (weight per unit length=1 g/1000 m=tex) or by number of filaments per yarn count, in thousands. For example 200 tex for 3,000 filaments of carbon fiber is 3 times as strong as 1,000 carbon fibers, but is also 3 times as heavy. This thread can then be used to weave a carbon fiber filament fabric or cloth. The appearance of this fabric generally depends on the linear density of the yarn and the weave chosen. Carbon fiber is naturally a glossy black but colored carbon fiber is also available.

Carbon fiber may be used to reinforce composite materials, particularly the class of materials known as carbon fiber reinforced plastics. This class of materials is often used in demanding mechanical applications. Carbon fiber's unique properties such as high stiffness, high strength, high damping, low density, and corrosion resistance are ideal for demanding applications. Carbon fiber/epoxy composites have mechanical properties such as the stiffness and strength of steel, and damping of 10 times more than aluminum at 30% lower density.

While non-polymer materials can also be used as the matrix for carbon fibers, due to the formation of metal carbides (i.e., water-soluble AIC), bad wetting by some metals, and corrosion considerations, carbon is used less frequently in metal matrix composite applications.

Vibration may interfere with the operation of HDDs, cooling fans and other server components resulting in reduction of performance and increase in energy consumption. Therefore there is a need for a means to minimize or eliminate vibration. In order to address the vibration, embodiments of the present invention provide for a novel anti-vibration rack (AVR) that dissipates vibration at wide frequency ranges. For example, the novel AVR may dissipate vibration from 10 Hz to several thousand and perhaps in several hundred thousand Hz. The frequency range of interest in HDD operation is preferably from 50 Hz to 2,000 Hz. Testing of various embodiments of the novel server AVR verify the effect of its anti-vibration technologies on servers' performance and energy consumption. Embodiments of the novel AVR dissipate vibration passively, effectively eliminating vibration in all interested frequency ranges.

### SUMMARY

One embodiment of the present invention provides an apparatus for dampening vibration from a server, a cross bar support, a cross bar housing, and anti-vibration modules wherein the anti-vibration modules are loaded by exerting a force on the anti-vibration modules and the cross bar support and cross bar housing create an assembly which is configured to couple a server slide rail rack to a server rack.

Another embodiment of the present invention provides an apparatus for dampening vibration from one or more of the following components, a server, other servers housed in the same rack, a server rack fan, a power distribution unit, adjacent server racks, a cross bar support, a cross bar housing, and anti-vibration modules wherein the anti-vibration modules are loaded by exerting a force on the anti-vibration modules and the cross bar support and cross bar housing create an assembly which is configured to couple a server slide rail rack to a server rack.

Other and further features and advantages of the present invention will be apparent from the following descriptions of the various embodiments. It will be understood by one of ordinary skill in the art that the following embodiments are provided for illustrative and exemplary purposes only, and that numerous combinations and modification of the elements of the various embodiments of the present invention are possible.

### BRIEF DESCRIPTION OF THE DRAWING

Non-limiting and non-exhaustive embodiments of the present invention are described with reference to the following drawings. In the drawings, like reference numerals refer to like parts throughout the various figures unless otherwise specified.

For a better understanding of embodiments of the present invention, reference is made to the following Detailed Description, which is to be read in association with the accompanying drawings, wherein:

FIG. 1 is a perspective view of an exemplar server rack system in accordance with an embodiment of the present invention;

FIG. 2 is a front view of an exemplar rack system in accordance with another embodiment of the present invention;

FIG. 3 is a perspective view of an exemplar server rack in accordance with an embodiment of the present invention;

FIG. 4 is a perspective view of a shelf support assembly in accordance with an embodiment of the present invention;

FIG. 5 is a perspective view of an anti-vibration mount in accordance with an embodiment of the present invention;

FIGS. 6A-6C are front views of exemplar brackets in accordance with embodiments of the present invention;

FIG. 7 is a perspective view of another exemplar server rack system in accordance with an embodiment of the present invention;

FIG. 8A is a rear view of the server rack system of FIG. 7;

FIG. 8B is a perspective view of the server rack system of FIG. 7 including side skins and a top panel;

FIGS. 9A-9C are alternate views of an exemplar cross bar support in accordance with an embodiment of the present invention;

FIGS. 10A-10D are alternate views of an exemplar cross bar housing in accordance with an embodiment of the present invention;

FIG. 11 is an isometric view of an exemplar cross bar support and cross bar housing assembly; and

FIG. 12 is an isometric view of an exemplar cross bar support and cross bar housing assembly with anti-vibration modules in place.

### DETAILED DESCRIPTION OF PREFERRED EMBODIMENTS

The embodiments of the present invention are described more fully hereinafter with reference to the accompanying drawings, which form a part hereof, and which show, by way of illustration, specific exemplary embodiments by which the invention may be practiced. This invention may, however, be embodied in many different forms and should not be construed as limited to the embodiments set forth herein; rather, these embodiments are provided so that this disclosure will be thorough and complete, and will fully convey the scope of the invention to those skilled in the art. Among other things, the present invention may be embodied as systems, or devices. The following detailed description should not to be taken in a limiting sense.

Throughout the specification and claims, the following terms take the meanings explicitly associated herein, unless the context clearly dictates otherwise. The phrase “in one embodiment” as used herein does not necessarily refer to the same embodiment, though it may. Furthermore, the phrase “in another embodiment” as used herein does not necessarily refer to a different embodiment, although it may. Thus, as described below, various embodiments of the invention may be readily combined, without departing from the scope or spirit of the invention.

In addition, as used herein, the term “or” is an inclusive “or” operator, and is equivalent to the term “and/or,” unless the context clearly dictates otherwise. The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.” The term “coupled” implies that the elements may be directly connected together or may be coupled through one or more intervening elements.

Embodiments of the invention provide anti-vibration methods implemented in novel anti-vibration racks (AVR) that may be used in data and server centers and in existing server racks and servers. In various embodiments the AVRs are designed to dissipate vibration. Embodiments of the invention providing for anti-vibration measures implemented on existing racks include novel shelf assemblies, novel anti-vibration server mount attachments and novel anti-vibration server feet support. Although the embodiments of the present invention are described in connection with servers, the embodiments are not so limited and are equally applicable to other electronic components or devices in which it is desirable to limit vibration or noise. In addition, the embodiments of the present invention may be used to limit vibration from other servers housed in the same rack as a server, a server rack fan, a power distribution unit, and adjacent server racks.

The anti-vibration mounts herein are defined as general spring-dashpot modules to support either the server directly and attach to the server rack as mounts or to be used as server feet supporting the server on the rack shelf.

The novel anti-vibration modules take a variety of forms including rubber-springs, air dashpots or any other variation of spring-dashpot offering proper stiffness and damping to dissipate vibration. The embodiments described herein are anti-vibration modules made from elastomer (rubber like material) and fiber re-enforced plastics. The elastomer may be polyurethane, and fiber re-enforced plastics may be carbon fiber/epoxy composites and fiberglass re-enforced plastics.

The anti-vibration modules described herein, dissipate vibration in all operating frequency ranges passively or actively. Active vibration dissipation modules are comprised of vibration sensors to sense vibration force and frequency and then automatically or manually adjust its stiffness and damping to counter it. In embodiments including air dashpots, the air pressure is adjusted to accomplish this task. A preferred embodiment as described in this disclosure is a passive anti-vibration rack. The use of materials like polyurethane, carbon fiber and fiberglass in the novel design presented herein provide vibration dissipation in wide ranges of frequencies. While not explicitly shown in the embodiments, it is contemplated with in the scope of the embodiment of the present invention that air dashpots may be incorporated as an additional vibration dissipation means, complimentary vibration dissipation means or alternatively as an exclusive means.

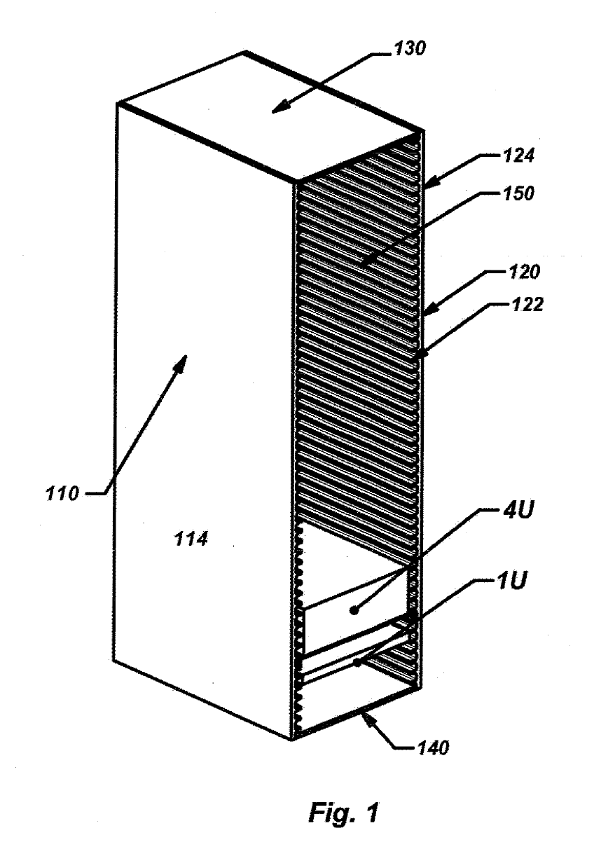

FIG. 1 depicts a perspective view of an AVR 100. The AVR 100 may preferably be designed and manufactured using aerospace structural and isolation principles. The AVR 100 is preferably constructed primarily from materials that assist in minimizing vibration and other interference. Carbon fiber composites are one such material and are one of the optimal materials for these purposes. Various acrylics are also suitable for such purpose. In contrast, glass and metals are less desirable for damping and minimizing the effects of vibration, oscillation and the like.

Carbon fiber composite materials offer an excellent damping/stiffness combination. When a structure, like an AVR is designed properly, it dissipates vibration the most effectively as it utilizes stiffness, damping and mass. That dissipation may be maximized by selecting a material well suited for the purpose, a carbon fiber composite is such a material.

The AVR 100 has a first side panel 110 and a second side panel 120. The AVR 100 also has an upper panel 130 and a lower panel 140. The first side panel 110, second side panel 120, upper panel 130 and lower panel 140 form a box-like structure having an open face 150. The upper panel 130, lower panel 140 and side panels 110, 120 may be constructed from materials as described above. In another embodiment some or all of the panels may be constructed from alternative materials. For example in one embodiment, some or all of the panels are plastic with or without fiberglass or carbon fiber reinforcement. In another embodiment, some or all of the panels are plastic with foam cores. In embodiments including foam cores, the panels may be molded with internal foam cores that are injected or comprised from sheets of foam. Alternatively, in embodiments including foam cores, the panels may be constructed as laminate layer with foam between the layers throughout or at the median of the layers. Preferably the upper, lower and side panels are ⅛″ to 1″ thick. However, in some instances it may be preferable to have thicker panels for example because of the strength needed to support the weight of the components contained in the cabinet.

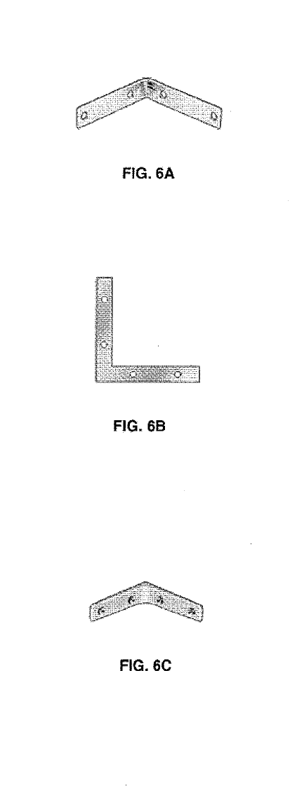

The first side panel 110 and the second side panel 120 each have an inner surface 112, 122 and an outer surface 114, 124. The outer surface 114,124 may be textured or smooth; the inner surface 112,122 is configured with grooves to support servers or other electronic equipment. Although depicted as a box like structure, this is not intended to be a limitation on the present invention. It is contemplated that an open shelving style system could also be constructed; in addition, it is contemplated that within a box like structure, additional side panels could be installed so that multiple sub-boxes exist within a larger box. In one embodiment, angled brackets may be attached at the inner or outer corners of the box like cabinet structure to strengthen the AVR. In another embodiment, angle brackets may be attached to the corner faces of the box like cabinet structure. FIGS. 6A-6C depict exemplar brackets. FIG. 6A illustrates a corner “L” bracket that may be fastened on the inside or outside surface of the AVR. FIG. 6B show a face mount “L” bracket configured to be mounted on the outside of the AVR. FIG. 6C depicts an inside corner bracket. The brackets shown are illustrative only and not intended to be a limitation on the size, or shape of bracket that may be utilized to further strengthen the AVR. Furthermore, the brackets may limit movement of the AVR thereby providing further strengthening. The brackets may be comprised of any commercially available material including but not limited to metal.

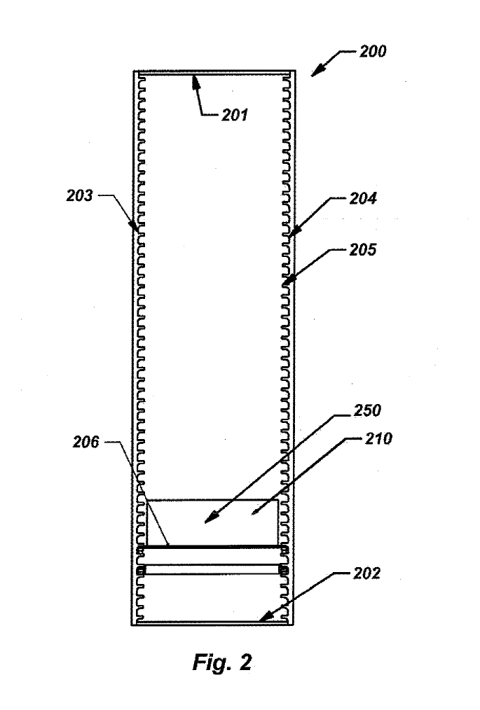

FIG. 2 is a front view on an AVR 200 according to an embodiment of the present invention. The AVR 200 described herein is designed to dissipate vibration passively in various frequencies, which interfere with operation of HDDs, cooling fans and other server components. The AVR 200 consists of a rack cabinet similar to that described in conjunction with FIG. 1. The AVR 200 may be constructed in various sizes and configuration so that the shelves and/or server mounts are capable of supporting various size servers. The configuration shown herein is not intended to be a limitation on the embodiments of the present invention. AVR 200 also referred to herein as a rack cabinet, consists of four sections: two side panels 203 and 204, an upper panel 201 and a lower panel 202. The side panels 201 and 202 have drawer type grooves 205 or other track systems for shelves. Other track systems that may be used include but are not limited to bars, retracting arms, ball bearing systems, peg systems, and fixed shelves.

A server 250 may be placed on a server shelf support assembly 206 and can then be slid in and out of an AVR. The server shelf assembly 206 may be constructed from any variety of materials. For example, carbon fiber composite or fiberglass composite materials offer an excellent damping/stiffness combination. The shelf assembly system 206 comprises a shelf plate 210, and two strip bars, one of polyurethane, i.e. sorbothane, and one of carbon fiber attached by fasteners (not shown), or other mechanical means, to the side of the shelf plate 210. The shelf plate 210 is of such a thickness that it is sufficient to support the weight of the server or other electronic component. The shelf plate 210 may be 0.1″ to 1″ inch thick. Preferably the shelf 210 is approximately 0.25″ thick. In one embodiment, a 1″ thick acrylic material shelf without fiber re-enforcement is implemented. The shelf plate 210 may be constructed from carbon fiber or fiberglass or any other suitable material. Fiberglass is preferably used for cost savings. In one embodiment having multiple shelves. one or more shelves are carbon fiber while the other one or more shelves are fiberglass. The carbon fiber shelves are preferably constructed using lamination techniques or molding techniques. The shelves may be constructed by molding or extrusion process or in the form of multiple plys of sheets of carbon fiber, i.e. laminate construction as disclosed above. Alternatively, the shelf plate 210 may be constructed from medium-density fiberboard (“MDF”) or MDF with a carbon fiber veneer. Furthermore, the shelf plate 210 may also be constructed from acrylics or similar plastic materials such as polymethyl methacrylate (also known as “acrylic glass” and “Plexiglas®”), the synthetic polymer of methyl methacrylate, or an acrylic with a carbon fiber veneer. When a carbon fiber veneer is used, the veneer is 10/1000 to 199/1000 inch thick and preferably 30/1000 to 35/1000 inch thick. The carbon fiber veneer described above is a multi layer carbon fiber skin (i.e. a laminate process) which is bonded to all surfaces (top, bottom and sides) of the MDF or acrylic to create the shelf. Carbon fiber (CF) veneer has sheets of CF fabric or unidirectional CF or CF mat pressed and cured to make a solid sheet. The fibers are generally placed along the veneer plane. The carbon fiber blocks used in vibration mounts (described below) are preferably made from laminated sheets of CF placed and cut at optimal angles, such that oblique angles are created between the plans of the sheets, to maximize its stiffness, strength and damping characteristics. Preferably the sheets are constructed from axisymetric solid laminated carbon fiber epoxy composite laminates with an oblique angle between the plane of laminate and top plane of the shelf to provide optimal stiffness and damping. More preferably the angle is about 20 degrees. The carbon fiber blocks may also be made from chopped carbon fiber epoxy using a molding or extruding process, in addition other similar methods maybe used to fabricate a mount. Regardless of fabrication method, the carbon fiber is preferably cut in the preferred optimal angle. In addition, ional metal wire may be added to the carbon fiber fabric to enhance shielding capability. Although depicted as having only a single shelf assembly 206, such is not intended to be a limitation and the AVR may have any number of shelves based on the height/size of the AVR.

The server shelf assembly 206 is supported on the grooves 205. The groves 205 are located on the inner surface of the side panels 203, 204 and are parallel to the shelf assembly rack 206. The grooves 205 preferably extend the full depth of the rack cabinet 200. However, it is not required that the shelf 210 and/or the groove 205 extend the entire depth of the rack cabinet 200. Preferably the groove 205 will run the length of the shelf assembly 206 so that the shelf assembly 206 is supported along its entire side length. The grooves 205 may be evenly spaced or unevenly spaced along the inner surface of the side panels 203, 204.

In one embodiment, the preferred method of fabrication of the rack cabinet 200 is molded fiberglass re-enforced plastics. The rack cabinet 200 may also be made with other materials and methods to reduce cost.

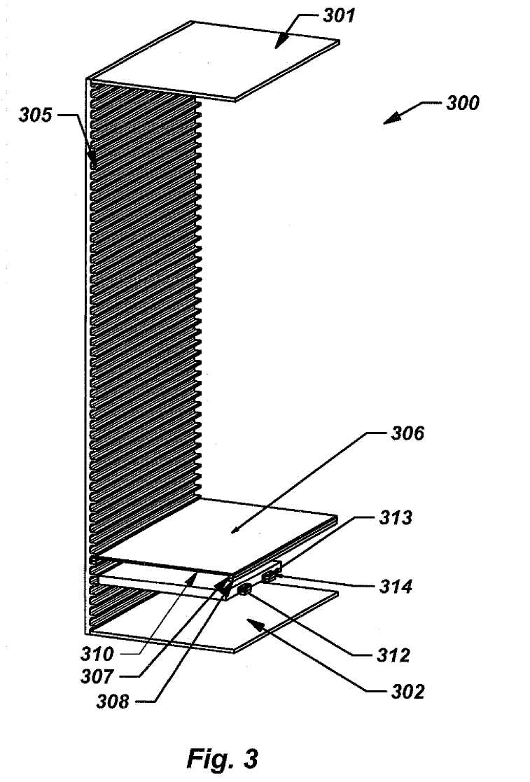

FIG. 3 depicts a cutaway perspective view of an AVR 300. The AVR 300 depicts a server 314 mounted directly in the rack cabinet 300 without a shelf plate supporting it and a shelf support assembly 310. Although depicted as having one shelf support assembly 310 and one direct mount server, this is not intended to be a limitation on the embodiments of the present invention, any combination of shelf assemblies and direct mounts may be utilized and are contemplated with in the scope of the present invention. The AVR 300 has an upper panel 301 and a lower panel 302

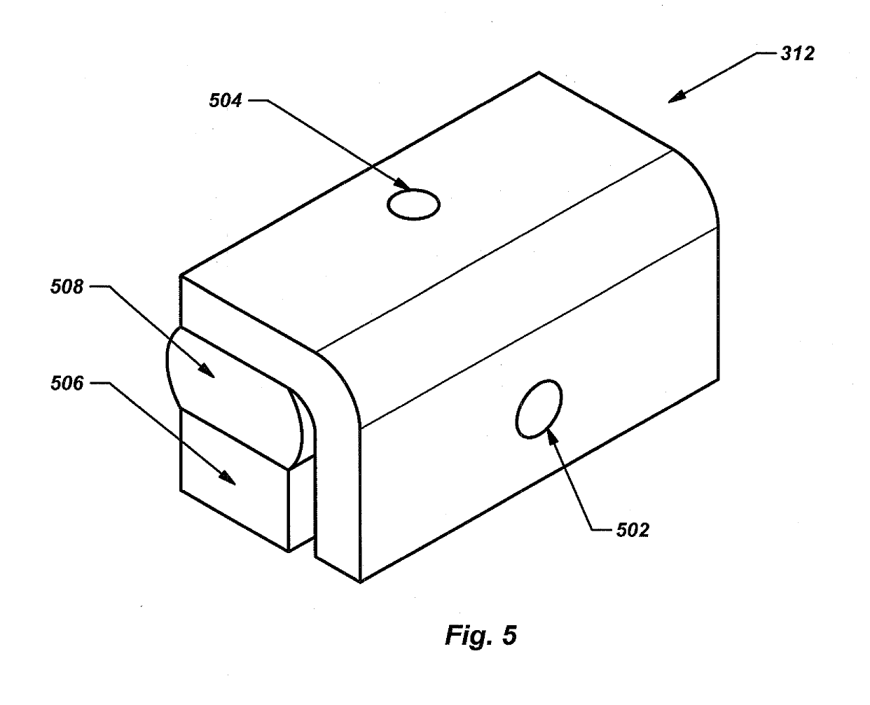

The server 313 which is mounted directly in the rack cabinet 300 has anti-vibration mounts 312 attached to the sides of the server. FIG. 5 depicts an exemplary anti-vibration mount 312. The anti-vibration mounts 312 may be comprised from elastomers, carbon fiber, or fiberglass, or any other material which has mechanical properties such that vibrational forces are absorbed. The anti-vibration mounts 312 have an inner surface and an outer surface. Preferably the mounts 312 are constructed as “L” brackets. However, this geometry is not intended to be a limitation on the shape of the anti-vibration mount.

The anti-vibration mounts 312 are configured with fastener holes 502, 504 to allow the mount to be attached to the sides of a server and compression blocks comprised of a carbon fiber block 506 and a polyurethane block 508. Although the compression blocks are depicted as being positioned on the inner surface of the bracket, this is not intended to be a limitation on the embodiments of the present invention, the compression blocks may also be positioned on the outer surface. Further, although described as being comprised of two blocks, the compression block may be comprised of a single block of any material capable of dissipating vibration or more than two blocks. The carbon fiber blocks dissipate vibration in mid and high frequency ranges while the polyurethane block dissipate vibration in low frequency range, generally below 200 Hz. The anti-vibration mount 312 is attached to the sides of a server via screws, using built-in screw holes on their sides for rack attachment. The polyurethane block 508 is compressed to its optimum compression which is preferably 10-15% by positioning it between the carbon fiber block 506 and the bracket. The anti-vibration mounts 312 are designed to ride and rest on the rack cabinet's 300 side grooves 305. The anti-vibration mounts 312 absorb the vibration from the server and allow it to be dissipated through the anti-vibration mounts 312 and the AVR 300.

In another embodiment, the mounts 312 are configured to be secured to the base of a component, i.e., as “feet”, when the component is positioned on a metal shelf of a metal rack or shelf support assembly of an AVR to further reduce vibration.

The shelf assembly 310 is preferably implemented to support larger and/or more critical servers for the optimum vibration dissipation while the server mounts 312, 313 generally support smaller and less vibration prone servers. Such preferred configuration is not intended to be a limitation on the embodiments of the present invention. It is contemplated within the scope of the embodiments that the size of the shelves and the mounts may vary to accommodate a variety of component sizes and specifications.

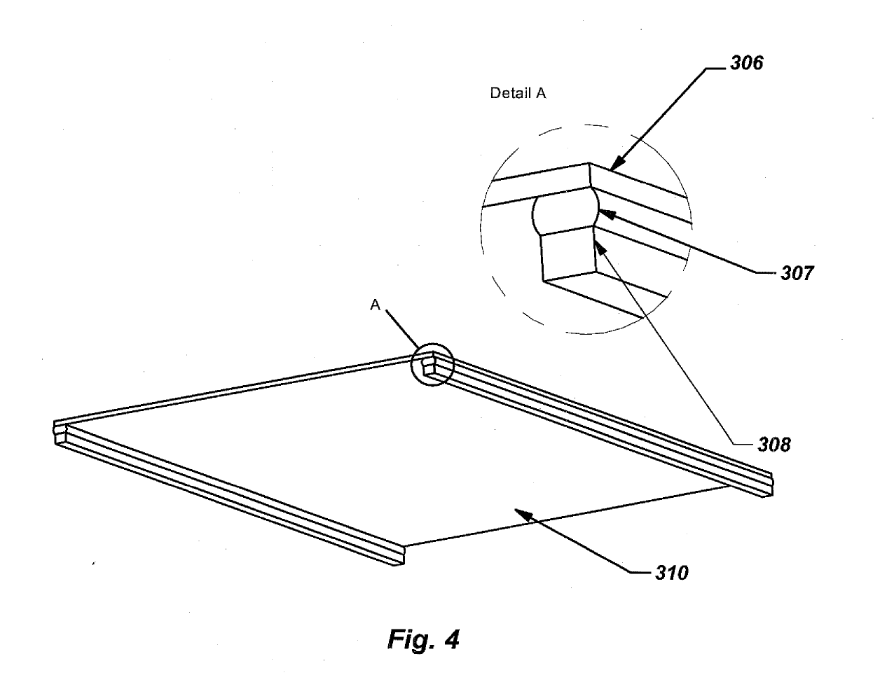

The shelf support assembly 306 is shown in detail in FIG. 4. The shelf support assembly 306 is comprised of a shelf plate 310 preferably made from re-enforced plastic like fiberglass re-enforced plastics, and two strip bars one of polyurethane, i.e. sorbothane, 307 and one of carbon fiber 308 attached by fasteners (not shown), or other mechanical means, to the side of the shelf plate. The polyurethane bar 307 is compressed to its optimum compression which is preferably 10-15% by positioning the polyurethane bar 307 between the carbon fiber bar 308 and the shelf plate fastener. The two side carbon fiber bars 308 are positioned and configured such that the carbon fiber bars 308 slide on the grooves 305 and sit in place on the grooves 305 when the shelf assembly 306 is positioned in the cabinet.

The server side mount system consists preferably of at least four mounts 312, more preferably, two mounts 312 are located on either side of the server such that the mounts 312 are able to slide along and be supported on the cabinet's grooves 305. In one embodiment, each side mount 312 consists of an “L” shape bracket 313 attached to the side of the server via a fastener, a polyurethane block/carbon fiber 314 that is positioned and compressed between the horizontal side of the “L” bracket 313 and a carbon fiber block 315 via a bolt or other mechanical fastener. The carbon fiber blocks 314 slides and rests on the wall grooves 305 of the cabinet. Although described as an “L” shaped bracket, such geometry is not intended to be a limitation on the embodiments of the present invention. The mounts 312 could be other shapes or configurations so long as the mount is capable of mating with the grooves 305. Similarly, the shelf 310 or the shelf assembly 306 may have a cross-section other that rectangular and the geometry of the grooves 305 may be adapted to accommodate such variations.

Optionally, front and back doors are provided to create an enclosure for the cabinet 300. In such a configuration, the doors attach to the side panels (not shown) via hinges and latches or other mechanical means. The doors may be solid, with meshed opening allowing for air circulation, or other venting means.

While the embodiment depicts grooves to support the shelf assembly systems and/or mounts attached to the servers or other electronic equipment, this is not intended to be a limitation on the embodiments of the present invention. Other means of attaching the shelf assembly system and side mounts to the rack cabinet are contemplated within the scope of the embodiments. Non-limiting alternative support means include, drawer closers with or without soft close mechanisms or other retraction control means, shelf brackets, direct attachment to the inner surface of the side panels; latching mechanisms; pegs or other hanging systems.

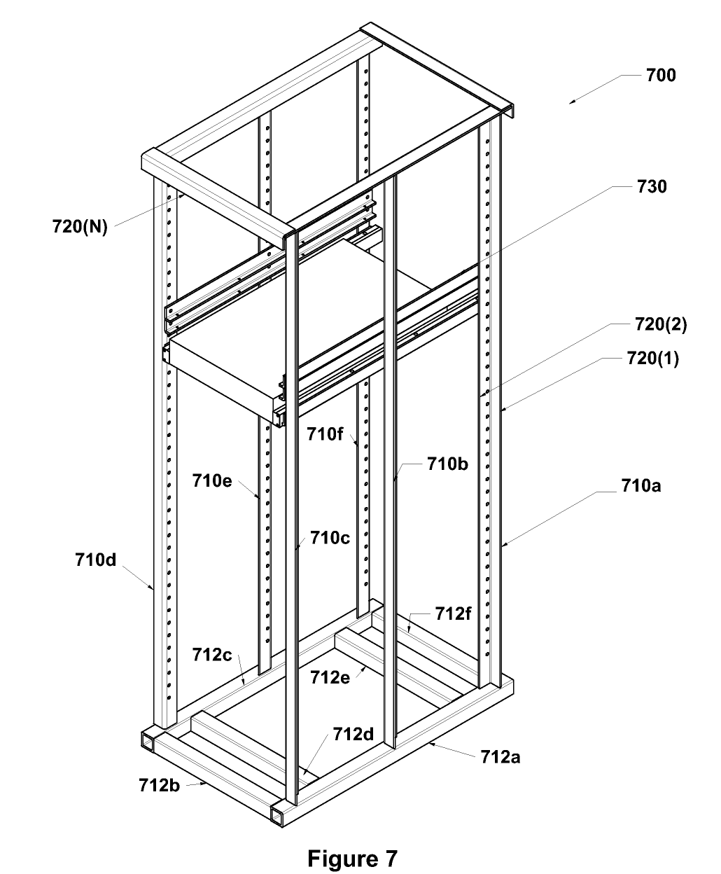

FIG. 7 depicts a perspective view of a structural frame of an AVR 700. The AVR 700 may preferably be designed and manufactured using aerospace structural and isolation principles. The AVR 700 is preferably constructed primarily from materials that assist in minimizing vibration and other interference. Carbon fiber composites are one such material. Pulltruded fiberglass is another such material. The use of pulltruded fiberglass or other reinforced plastic is desirable as such materials reduce vibration and controls vibration that is transmitted to the material. In addition, such materials have advantageous mechanical characteristics including strength, rigidity and dampening capabilities. The frame of the AVR 700 is comprised of multiple pulled through fiberglass members 710(a-f). The structural members 710(a-f) form a frame of the AVR 700. The structural members 710(a-f) may vary in size and geometry. The geometry of the cross section of the structural members 710(a-f) may vary and include but are not limited to square, “T”, “L”, channel, or tubular. Furthermore the structural members 710(a-f) may be hollow or solid. The size and thickness of the structural members 710(a-f) may vary as well. For example the structural members may be 1″-5″ in width of the cross sectional member while the thickness may be for example 0.1″ to 0.5″. The base members 712(a-f) and upper members (not shown) may be the same geometry and material as the structural members 710(a-f) or may be distinct. Although depicted with six structural members 710(a-f) and six base members 712(a-f), this is not intended to me a limitation on the embodiments of the present invention a lesser or greater number of structural members and base members as well as upper members may be utilized.

There are openings 720 (1 . . . N) along the length of each of the structural members 710(a-f). The openings may be created by any means for example the openings may drilled or punched or molded along the structural member. The openings facilitate the attachment of servers to the structural frame of the AVR 700 through the use of cross bars supports 730.

The structural members 710(a-f) are coupled to the base members 712(a-f) and upper members to create the AVR 700 structural frame. Optionally there may be cross-bracing, trussing or other additional structural members (not shown) for additional strength. The structural members 710(a-f) may be coupled to the base members 712(a-f) and upper members using any of a variety of means, including but not limited to: adhesive, bracing, bracketing, mechanical fasteners (i.e., screws, buts/bolts), epoxy bonding, and/or heat welding. Such coupling means may be implemented alone or in combination.

Although the AVR 700 is shown and described above as being comprised of multiple members coupled together, the AVR 700 may be molded as a single piece thereby eliminating the joints and need to couple the various members together. The AVR 700 if molded may be comprised of a variety of materials as described above. The AVR may be molded from chopped and continuous fiberglass or carbon fibers. If the AVR 700 is molded as a single piece, the cross bar supports 730 may be molded as part of the piece or the piece may be molded and designed such that the cross bar supports may be added later. If added later, the cross bar supports 730 may be coupled to the structure in a variety of ways including the use of mechanical means such as screws, adhesives, or heat welding.

Although not shown, the structural members of the AVR 700 are optimally covered on the exterior sides with a skin. The skin may be sheet plastic or any other nonporous material. The skin prevents side to side air flow through the structural members, and also aids in ensure the security and safety of the servers that may be stored in the AVR 700. Additionally, not shown are front, back, top and bottom panels. The front and back panels are doors preferably constructed from solid non-porous materials with venting incorporated in the material, i.e., the material may be a mesh, a plastic panel with venting openings to allow for air circulation. The top and bottom panels may be similarly constructed with or without venting.

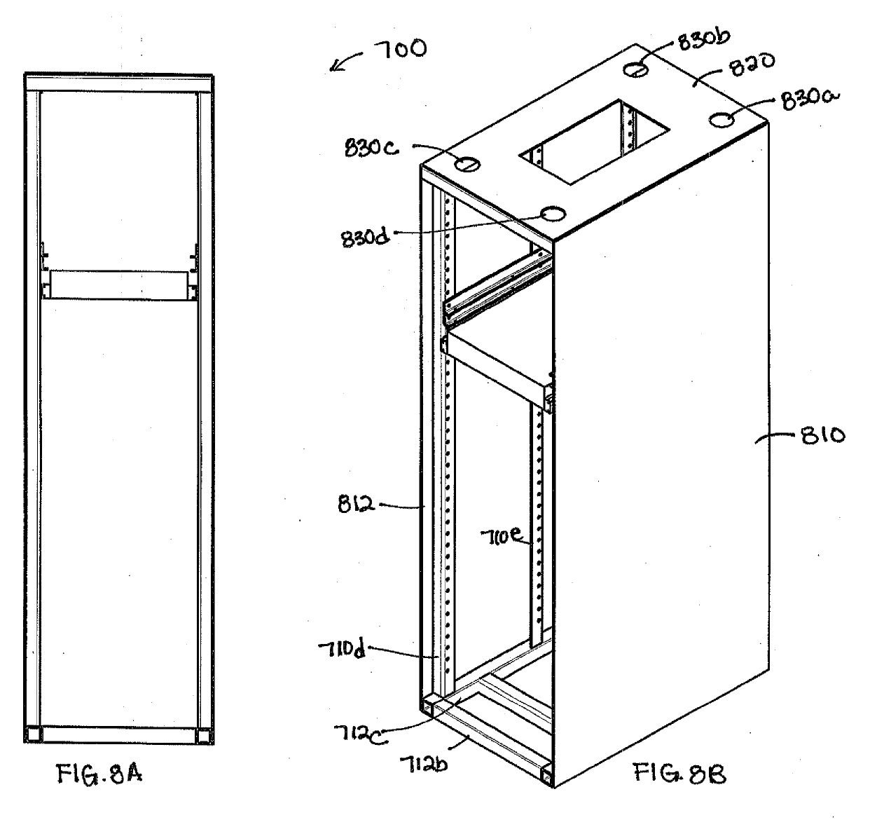

FIG. 8A is a rear view of the server rack system 700. One skilled in the art will recognize that the front view nearly mimics the rear view of a server rack, although the front as opposed to the back of the server is displayed.

FIG. 8B depicts a perspective view of the server rack system 700 including exterior sides with skins 810, 812. Also depicted are top 812 and bottom panels. The top panel 820 may be configured with openings 830(a-d) to allow for access for networks cables and other connections. Although shown as a 19 inch 42U rack, this is not intended to be a limitation on the embodiments of the present invention, other sizes and configurations of server rack systems are contemplated within the scope of the present invention. In addition, although the AVR 700 is shown with a 2 U server, the embodiments of the invention are not so limited and the server rack systems contemplated within the scope of the present invention are contemplated to accommodate 1 U, 2 U, 3 U, 4 U or 6 U servers or any other size server.

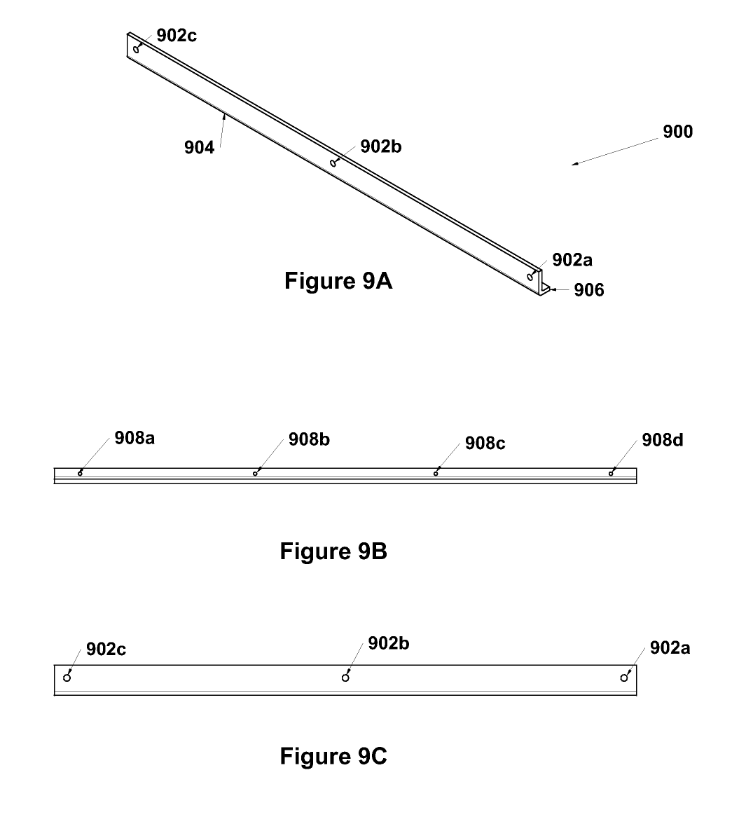

FIGS. 9A-9C are alternate views of an exemplar cross bar support, such as the support depicted in FIG. 7, 730.

FIG. 9A depicts a perspective view of a cross bar support 900. The cross bar support 900 is an elongated member having at least two sides 904, 906. As depicted the cross bar support 900 is an “L” shaped member sized for a 19″ server rack. The dimensions shown, for cross bar support 900, however are not intended to be a limitation on the embodiments of the present invention. The cross bar support 900 is configured with openings 902 (a-c). The openings 902(a-c) are spaced appropriately so that the cross bar member may be connected to the structural members of the AVR. Although depicted with three openings 902(a-c), this is not intended to be a limitation on the embodiments of the present invention, if an AVR is designed with fewer or greater structural members, the number of openings on the cross bar support member may be adjusted appropriately.

In another embodiment the cross bar support is comprised of three supports (or the same number of supports as there are structural members 710). The short cross bars supports are attached to the same level of structural member 710(a-e) on each side with one or two horizontal holes corresponding to the number horizontal openings of structural member 710 (a-e). This embodiment allows material savings of cross bars in part because the total length is less. In another embodiment there are two short cross bar support members of each side, one each coupled to the front structural members, for example 710c, 710d and one each coupled to the back structural members, for example 710a, 710f.

FIG. 9B is a plane view of the cross bar support 900.

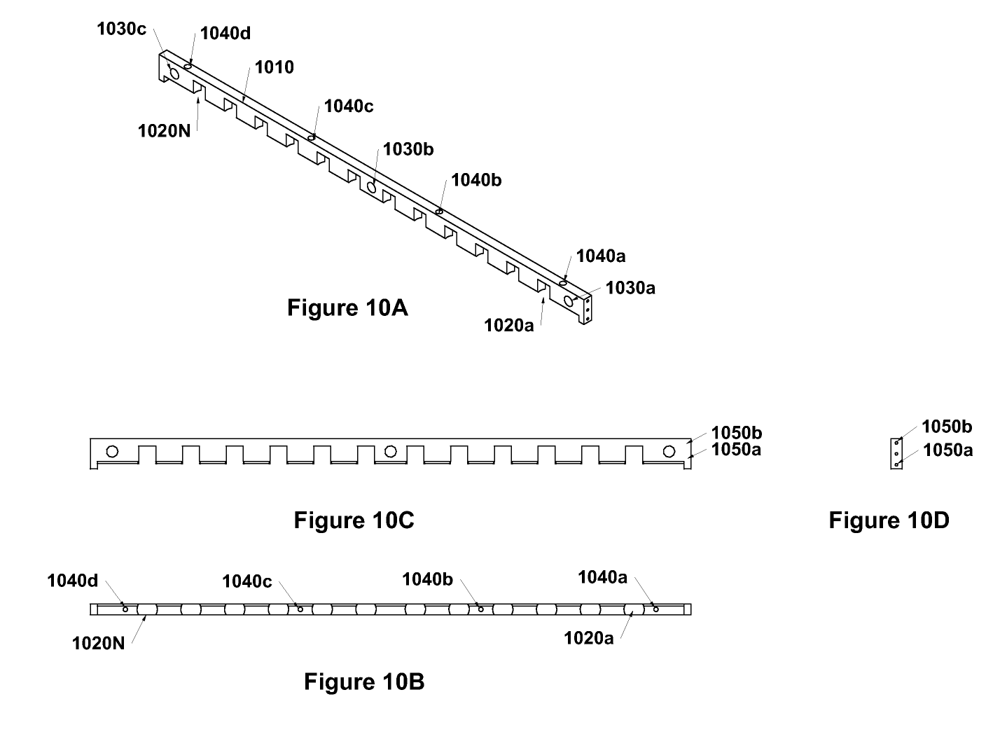

FIG. 9C is a bottom view of the cross bar support 900. The bottom of the cross bar support 900 is configured with multiple opening 908(a-d). The openings 908(a-d) are configured to enable the attachment of the cross bar housing 1000, described below in conjunction with FIGS. 10A-D, to the cross bar support 900. Although depicted with four openings 908(a-d), this is not intended to be a limitation on the embodiments of the present invention. A lesser or greater number of openings may be implemented as desired to provide the appropriate support and stability based on the size and load of the server unit or other component the cross bar support will hold.

In use, each server or other component is supported in the AVR by two cross bar supports or two sets of cross bar supports when the shorter cross bar supports are implemented, located on opposite sides of the component.

FIGS. 10A-10D depict alternate views of an exemplar cross bar housing 1000. The cross bar housing 1000 may be comprised from any suitable substance that has the appropriate structural and materials properties, for example the cross bar housing 1000 may be aluminum or composite fiberglass. The cross bar housing 1000 may be constructed using molding techniques, pulltrution, lamination or any other appropriate manufacturing process. The dimensions depicted in FIGS. 10A-10D are exemplar only and are not intended to be a limitation on the size or dimensions of the cross bar housing 1000. The cross bar housing may be custom and constructed to adapted to an unlimited variety of configurations.

FIG. 10A is an isometric view of the cross bar housing 1000. The cross bar housing 1000 is an elongated member having a first end and a second end. The cross bar housing 1000 has through openings 1020(a . . . N) along the length of the elongated member. As shown, the openings 1020 (a . . . N) are cutouts or cavities. Such geometry is not intended to be a limitation on the embodiments of the present invention. The openings 1020 (a . . . N) along the length of the elongated member may be a single elongated channel, multiple elongated channels, or any other geometry. Each opening is configured to accommodate an anti-vibration module. Preferably the anti-vibration module is comprised of an elastomer module (rubber like material) coupled to a fiber re-enforced plastic module. Where the elastomer may be polyurethane and fiber re-enforced plastic may be a carbon fiber/epoxy composite and/or a fiberglass re-enforced material. The anti-vibration modules are designed to fit within the openings 1020(a . . . N) of the cross bar housing and are flush with the horizontal surface.

Along the vertical length of the cross bar housing 1000 there are openings 1040(a-d). The number and spacing of the openings 1040(a-d) shown are not intended to be a limitation on the embodiments of the present invention, alternate spacing and numbers of openings are contemplated within the scope of the present invention. The openings 1040(a-d) are provided so that the cross bar housing 1000 may be coupled to the cross bar support 900. Preferably the number of openings 1040(a-d) on the vertical length of the cross bar housing is the same as the number of openings 908(a-d) on the cross bar support 900.

The openings 1040(a-d) are also used to load the anti-vibration modules to specified compression in order to optimize the anti-vibration measures, i.e., the dampening and spring characteristics, of the AVR 700. Preferably the anti-vibration modules are loaded to a compression of 15% of the thickness of the elastomer. The 15% compression however is not intended to be a limitation on the embodiments of the present invention and alternate compressions may be loaded. Preferably the range of compressions is 10%-25%. When the anti-vibration modules are loaded the cross bar housing 1000 is coupled to the cross bar support 900. However, the cross bar housing 1000 remains raised from the horizontal surface of the cross bar support 900 by means of the anti-vibration modules. Therefore, the housing only “touches” the crossbar support member through the anti-vibration modules. This novel configuration results in the server being isolated from the AVR and the other servers located in the AVR but enables the server to nonetheless fit within the available space in the AVR.

There may be a fewer or greater number of openings 1040(a-d) along the vertical length of the cross bar housing 1000 to create an even loading of the anti-vibration modules and provide the proper support for a server when in the AVR 700 and when being removed from the AVR 700, as when a slide rail guide rack (described below) is extended outside the AVR 700. When full length cross bar supports are implanted as depicted in FIG. 9 there are however, at least two openings along the vertical length of the cross bar housing to ensure adequate and uniform loading.

Along the horizontal length of the cross bar housing 1000 are openings 1030(a-c). Openings 1030(a-c) are clearance openings to allow the cross bar support 900 and cross bar housing 1000 to be attached to the structural members 710(a-f).

FIG. 10B is a bottom view of the cross bar housing 1000.

FIG. 10C is a front view of the cross bar housing 1000. At the first end of the cross bar housing 1000 are opening 1050a, 1050b. Similar openings are located at the second end of the cross bar housing. Openings 1050a, b provide for the coupling of a sever slide rail to the cross bar housing. The openings 1050a, b may be adapted to accommodate any server slide rail including those conventionally available. Although shown as having two openings 1050a, 1050b, this is not intended as a limitation on the embodiment of the present invention. If additional opening are necessary to couple a server slide rail to the cross bar housing 1000, i.e., three, such is contemplated within the scope of the embodiments of the present invention.

FIG. 10D is an end view of the first end of the cross bar housing showing the openings 1050a,1050b for coupling a server rail to the cross bar housing 1000. A server slide rail kit may be coupled to the cross bar housing through mechanical fasteners rather than coupling the server slide rail kit to a server rack itself.

When short cross bar supports are used, a corresponding number of short cross bar housings are employed. In this embodiment, each short cross bar housing will have the same attributes as described in conjunction with the full length cross bar housing of FIG. 10.

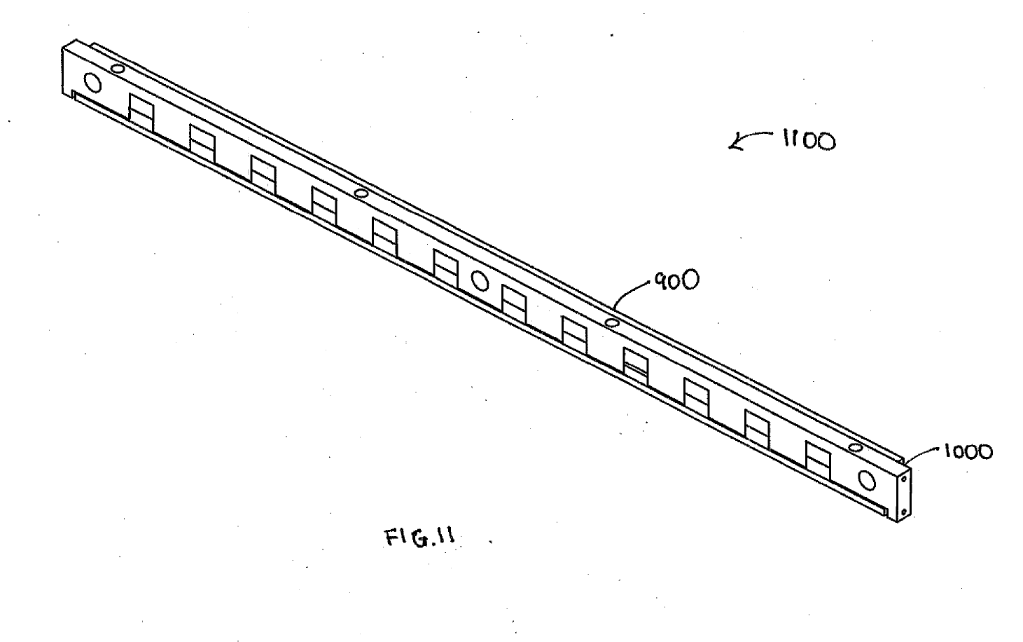

FIG. 11 is an isometric view of an exemplar cross bar support and cross bar housing assembly 1100. The cross bar housing 1000 is mounted on the cross bar support 900. When properly positioned, the first and the second ends of the cross bar housing extend beyond the length of the cross bar support 900. The extension of the housing prevents the cross bar housing from touching the cross bar support so that there is no transfer of vibration without the vibration going thru the anti-vibration module.

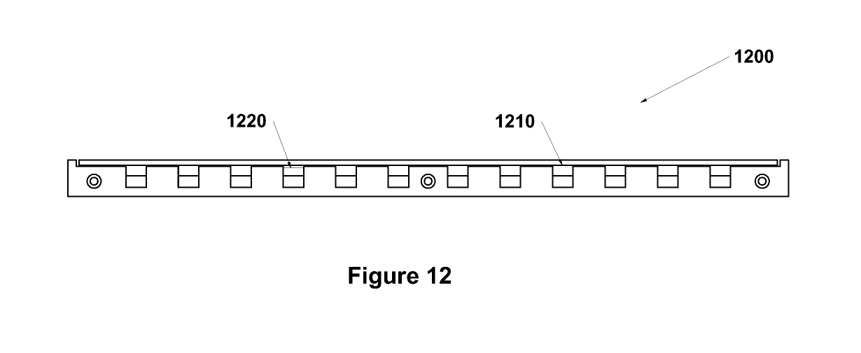

FIG. 12 is an isometric view of an exemplar cross bar support and cross bar housing assembly 1200 with anti-vibration modules in place. The anti-vibration modules are positioned in the cavities, or cut outs in the cross bar housing. As depicted in FIG. 12, anti-vibration modules are placed in each opening except two, 1210, 1220. This exemplar configuration illustrates that the anti-vibration modules may be custom loaded according the mechanical properties desired. For example, a server may weight 250 pounds and necessitate a large number of anti-vibration modules while a lighter server may require fewer. In one embodiment where the component exerts a large load, there are at least two anti-vibration modules included in the assembly to ensure uniform loading.

An additional novel safety feature of embodiments of the present invention is that if there is too much load when a heavy server is pulled out of the AVR (i.e., the server slide rail is extended from the cross bar housing, the cross bar housing directly contacts the cross bar support and is therefore supported by the cross bar support member instead of the anti-vibration modules, which may be fully compressed. This configuration provides more support that a server slide rail provides on its own.

In another embodiment the cross bar housing and the carbon fiber component of anti-vibration module are combined together. In this embodiment the cross bar housing may be comprised of carbon fiber or fiber glass re-enforced plastics or even neat (no re-enforcement) plastics. The carbon fiber or fiberglass re-enforced plastic maybe made by pulltrusion, lamination, chopped fiber molding or other techniques. In this embodiment polyurethane elastomer is still used in a compressed state similar as described above in FIG. 10.

In another embodiment, the cross bar housing, carbon fiber anti-vibration module and the cross bar support are combined as one part comprised of carbon fiber, fiberglass or neat plastic. The carbon fiber or fiberglass parts may be made by pulltrusion, lamination, molding with continuous or chopped fiber re-enforcement. In this embodiment, the polyurethane component of the anti-vibration module is placed between the combined cross bar support and the structural member 710(a-e). The server slide-rail is attached directly to the cross bar support. This embodiment provides for a simpler construction that may be less costly.

Embodiments of the present invention also include methods for reducing vibration of a component in a rack having a support means on either side of the rack inner side panels. The method includes positioning the component on a carbon fiber shelf having at least two opposite sides; attaching at least one compression block to each of the at least two opposite sides of the carbon fiber shelf; and placing the carbon fiber shelf with the component on the carbon fiber shelf in the rack such that each of the at least one compression block mates with the support means located on either side of the rack.

As noted previously the forgoing descriptions of the specific embodiments are presented for purposes of illustration and description. They are not intended to be exhaustive or to limit the invention to the precise forms disclosed and obviously many modifications and variations are possible in view of the above teachings. The embodiments were chosen and described in order to explain the principles of the invention and its practical applications, to thereby enable those skilled in the art to best utilize the invention and various embodiments thereof as suited to the particular use contemplated. It is intended that the scope of the invention be defined by the claims and their equivalents.

1. An apparatus for dampening vibration from component in or near a server comprising:
a cross bar support;
a cross bar housing;
at least one anti-vibration module wherein the at least one anti-vibration module is loaded by exerting a force on the anti-vibration modules; and
the cross bar support and cross bar housing create an assembly which is configured to couple a server slide rail rack to a server rack.

2. The apparatus of claim 1, wherein the components include at least one of the following components: a server, other servers housed in the same rack, a server rack fan, a power distribution unit, and adjacent server racks.

3. The apparatus of claim 1, wherein the cross bar support comprises:
at least one elongated member having at least two sides; and
at least one opening along each of the at least two sides of the elongated member.

4. The apparatus of claim 3, wherein the cross bar support has an “L” shaped cross section.

5. The apparatus of claim 1, wherein the cross bar housing comprises:
an elongated member having a first end and a second end;
at least one through opening along the length of the elongated member; and
at least one anti-vibration module positioned in the at least one through opening.

6. An apparatus for dampening vibration comprising:
at least two elongated structural members at least two elongated base members;
at least one opening along the length of each of the at least two elongated members;
at least two cross bar supports, wherein each one of the at least two cross bar supports is coupled to at least one cross bar housing and each at least two cross bar supports is coupled to at least one of the at least two elongated structural members;
at least two anti-vibration modules coupled to each of the at least two cross bar housings, wherein the at least two anti-vibration modules are loaded by exerting a force on the anti-vibration modules.
